(19) United States
(12) Patent Application Publication
(10) Pub. No.: US 2025/0201509 A1
(43) Pub. Date: Jun. 19, 2025

(54) High-Volume Transmission Electron Microscopy Grid

(71) Applicant: Yale University, New Haven, CT (US)

(72) Inventor: Cong Su, Albany, CA (US)

(73) Assignee: Yale University, New Haven, CT (US)

(21) Appl. No.: 18/984,006

(22) Filed: Dec. 17, 2024

Related U.S. Application Data
(60) Provisional application No. 63/611,295, filed on Dec. 18, 2023.

(51) Int. Cl. H01J 37/20; H01J 37/26

(52) U.S. Cl. CPC H01J 37/20; H01J 37/26; H01J 2237/204

(57) ABSTRACT

High-volume transmission electron microscope grid assemblies are provided that improve the efficiency/throughput associated with TEM testing by enhancing the efficiency and effectiveness of sample delivery to (and removal from) the TEM. Sample exchange time is reduced through utilization of a TEM grid assembly that includes a plurality of individual grids that are individually mountable relative to a base and that receive/contain multiple samples. A securing or locking mechanism may be incorporated into the TEM grid so as to secure/fix each individual grid relative to the base, thereby facilitating delivery of the individual grids to the TEM as part of an integrated TEM grid assembly.

### CROSS-REFERENCE TO RELATED APPLICATION

The present application claims priority benefit to a US provisional application entitled “High-Volume Transmission Electron Microscopy Grid,” which was filed on Dec. 18, 2023, and assigned Ser. No. 63/611,295. The entire content of the foregoing provisional application is incorporated herein by reference.

### BACKGROUND OF THE INVENTION

### 1. Field of the Invention

The present disclosure is directed to systems and methods for improving efficiencies associated with transmission electron microscopy procedures and, more particularly, to high-volume transmission electron microscope grid assemblies that facilitate high-volume sample testing.

### 2. Description of Related Art

Materials characterization using transmission electron microscope (TEM) technology is critical for materials science analysis and discovery. In conventional TEM procedures, a TEM grid is utilized for delivery of samples to be imaged within the TEM. Typical TEM grids are fabricated from thin copper or gold foil and support a single sample for TEM-based testing.

A typical TEM procedure involves introducing the sample-containing TEM grid into a TEM column (maintained at high vacuum) through an antechamber. The TEM process involves vacuum pumping and realignment of the electron beam in connection with each sample introduction, and the TEM procedure generally requires 20-30 minutes to exchange a single TEM grid/sample. For some ultra-high vacuum TEMs, e.g., the UltraSTEM™ instrument (Nion Company, Kirkland, WA), the pumping process takes even longer, and the quantity of samples that may be imaged per day is limited by the sample slots in the magazine associated with the UltraSTEM™ instrument (usually 5). As a result, significant time is lost in the sample exchange process, thereby minimizing the utility of the TEM and associated “beam time,” and disadvantageously limiting the number of samples that may be characterized with the TEM instrument.

A need exists for improved sample introduction to TEM instrumentation for testing/analysis that minimizes the lost “beam time” without sacrificing the efficacy of the TEM testing/analysis.

### SUMMARY OF THE INVENTION

The disclosed high-volume transmission electron microscope grid assemblies improve the efficiency/throughput associated with TEM testing by enhancing the efficiency and effectiveness of sample delivery to (and removal from) the TEM, thereby minimizing lost “beam time” associated with sample delivery to (and sample removal from) the TEM instrument.

In embodiments, sample exchange time is reduced through utilization of a TEM grid assembly that includes a plurality of individual grids that are individually mountable relative to a base and that are configured and dimensioned to receive/contain multiple samples, thereby increasing sample throughput for TEM testing/analysis and enhancing the efficiency and cost-effectiveness of TEM-based testing/analysis modalities.

In embodiments, a securing or locking mechanism may be incorporated into the TEM grid so as to secure/fix each individual grid relative to the base, thereby facilitating conjoint delivery of the individual grids to the TEM as part of an integrated TEM grid assembly. The individual grids may include indicia that allow identification of the individual grid and its associated sample(s) throughout the testing/analysis process.

In an exemplary embodiment, a TEM grid assembly may include a base that is configured and dimensioned to receive/deliver a plurality of individual grids, e.g., six (6) individual grids. In the exemplary embodiment, each individual grid is adapted to receive/contain one or more samples. Thus, when fully assembled, the TEM grid assembly facilitates delivery of multiple samples, e.g., six discrete samples associated with six discrete grids—to a TEM for testing/analysis. In exemplary embodiments, the TEM grid assembly is estimated to save at least one (1) hour of beam time based on more efficient sample exchange as compared to conventional, single sample delivery techniques.

Implementation of the disclosed TEM grid also translates to a reduced risk of downtime/damage for the TEM because the reduced need to break the vacuum of the TEM system reduces a primary driver of TEM-related breakage.

Additional features, functions and benefits of the disclosed high-volume TEM grid assembly will be apparent from the description which follows, particularly when read in conjunction with the accompanying figures.

### BRIEF DESCRIPTION OF THE FIGURES

To assist those of skill in the art in making and using the systems and methods of the present disclosure, reference is made to the figures, wherein;

FIG. 1 is a schematic depiction of a TEM grid assembly according to the present disclosure;

FIG. 2 is a schematic depiction of an exemplary base component associated with a TEM grid assembly according to the present disclosure;

FIG. 3 is a partially exploded view of a TEM grid assembly with two of the grids spaced away from associated openings defined by the base;

FIG. 4 is a further schematic depiction of a TEM grid assembly according to the present disclosure; and

FIG. 5 is a further schematic depiction of an exemplary base component associated with a TEM grid assembly according to the present disclosure.

### DETAILED DESCRIPTION OF EMBODIMENTS

The disclosed systems and methods improve the efficiency of TEM testing by enhancing the efficiency and effectiveness of sample delivery to (and removal from) the TEM. Sample exchange time is reduced according to the present disclosure through utilization of a TEM grid assembly that is configured and dimensioned to contain multiple samples for simultaneous testing/analysis. The ability to simultaneously introduce and position multiple samples in a TEM reduces the number of times the TEM system must be cycled through a sample introduction protocol to test a sequence of samples, thereby increasing sample throughput for the TEM and enhancing the efficiency and cost-effectiveness of TEM-based testing modalities.

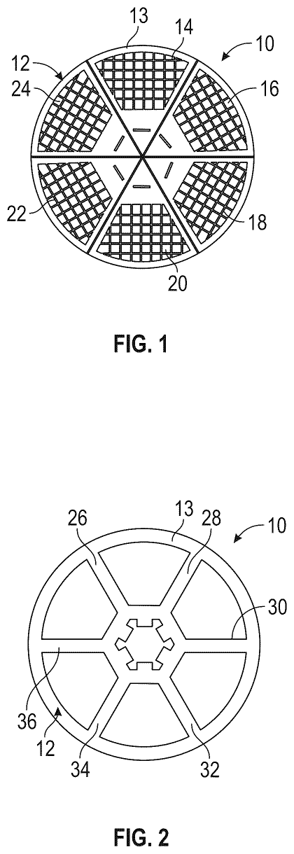

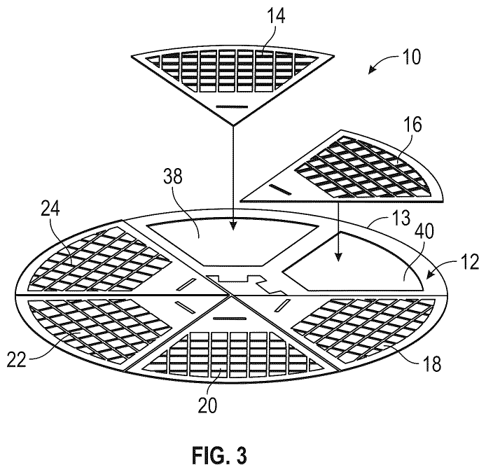

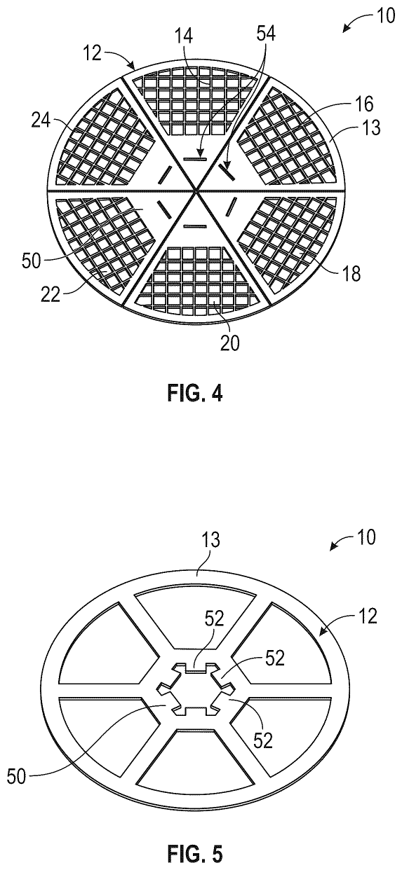

With reference to FIGS. 1-5, schematic depictions of TEM grid assembly 10 and/or components thereof are provided. TEM grid assembly 10 includes a base 12 that defines an outer rim 13 and a plurality of pie-shaped grids 14, 16, 18, 20, 22, 24 that are configured and dimensioned to cooperate with struts 26, 28, 30, 32, 34, 36 associated with base 12. A plurality of pie-shaped openings, e.g., openings 38, 40 as shown in FIG. 4, are defined between adjacent struts and are configured/dimensioned to receive an individual pie-shaped grid.

The exemplary embodiment of FIGS. 1-5 includes six (6) struts that define six (6) pie-shaped openings of substantially equal size/shape. Each of the openings is configured/dimensioned to receive a grid that defines a comparable pie-shaped geometry. In the exemplary embodiment of FIGS. 1-5, each of the six (6) pie-shaped grids are similarly sized and shaped. However, the present disclosure is not limited by or to implementations wherein the openings are equally sized/shaped and/or implementations wherein the grids are equally sized/shaped.

Rather, the number of grids to be mounted with respect to the base of the TEM grid assembly may include, for example, 2 grids, 3 grids, 4 grids, 5 grids, 6 grids (as shown), 7 grids, 8 grids, 9 grids, 10 grids, 11 grids, or 12 grids. It is possible to include greater than twelve (12) grids in a TEM grid assembly, but it may be challenging to handle designs that include greater than twelve (12) grids, and assemblies with twelve or fewer grids are generally sufficient and effective.

Similarly, the present disclosure is not limited by or to implementations in which the openings defined by the struts and/or grids are equally sized/shaped. For example, a first grid could be sized/shaped to encompass 60° of the circumference of base 12, a second grid could be sized/shaped to encompass 120° of the circumference of base 12, and a third grid could be sized/shaped to encompass the remaining 180° (or half) of the circumference of base 12. In a second example, first, second, third and fourth grids could each be sized/shaped to encompass 45° of the circumference of base 12, and a fifth grid could be sized/shaped to encompass the remaining 180° (or half) of the circumference of base 12. These two examples are merely illustrative, and any combination of opening/grid sizes and geometries may be implemented according to the present disclosure, subject only to ensuring that the individual grids are effectively secured relative to the base of the TEM grid assembly and, from a practical standpoint, that handling of the grids and associated samples may be effectively undertaken by users of the disclosed TEM grid assemblies.

In exemplary implementations, the base may be designed to accommodate a specific combination of grids. For example, as shown in FIGS. 1-5, base 12 is designed to receive and support six (6) equally sized/shaped grids, each of which encompasses 60° of the circumference of the base. In alternative embodiments, the struts associated with the base may be designed so as to allow grid(s) to overlay the strut(s), thereby allowing grid(s) that are greater in angular extent than the opening defined between adjacent struts to be supported by the base and associated with the disclosed TEM grid assembly. Thus, in an exemplary implementation, the struts may be spaced by 15° around the circumference of the base, but may be dimensioned so as to allow grid(s) to overlay the struts. According to this exemplary embodiment, the base may be effective in receiving/supporting grids that define any angular extent that is divisible by 15, e.g., a grid that encompasses 15°, a grid that encompasses 30°, a grid that encompasses 45°, a grid that encompasses 60°, etc. The “divisible-by-fifteen” implementation is but one possible implementation. Alternative implementations could be undertaken that space the struts by 20°, 30°, 40°, 60°, etc. in like measure.

In further exemplary implementations, the struts associated with the base are not equally spaced from each other. Thus, for example, a first strut and a second strut may be spaced relative to each other to define a first opening that encompasses 15° of the circumference of the base, a third strut may be spaced from the second strut to define a second opening that encompasses 30°, a fourth strut may be spaced from the third strut to define a third opening that encompasses 45°, and a fifth strut may be spaced from the fourth strut to define a fourth opening that encompasses 90°. The first strut and the fifth strut may then define a fifth opening that encompasses the remaining 180° of the circumference of the base. In such exemplary implementation, individual grids may be provided/utilized that correspond to the respective sizes of the first, second, third, fourth and fifth openings, and samples may be received/contained by the grids of differing size for delivery to the TEM for testing/analysis by the assembled TEM grid assembly that includes the noted grids of differing size. The foregoing example is merely illustrative, and other angular variations/combinations may be implemented without departing from the spirit or scope of the present disclosure.

Thus, the TEM grid assembly system disclosed herein provides significant flexibility in implementation and use. For example, a user's selection of base and sample grid(s) can be based on his/her needs and/or the testing to be accomplished in a particular instance. The user can select a base and combination of sample grids that effectively leverages “beam time” of the TEM while processing samples that potentially may have been prepared by different methods and/or at different times.

With further reference to FIGS. 4 and 5, base 12 includes a central region 50 that defines a plurality of attachment structures/elements 52 (FIGS. 4 and 5) that are configured and dimensioned to engage with cooperating structures/elements 54 (FIG. 4) defined by or associated with each of the grids. Central region 50 may define an inner ring or polygonal structure from which the struts may extend. The attachment structures/elements 52 may take the form of pins or extensions that may be bent into engagement with a cooperating structure/element 54 that may take the form of a slit, slot or channel. By engaging pin/extension 52 with slit/slot/channel 54, a grid may be detachably engaged with a base so as to provide security and stability of the samples associated with the individual grids. Alternative engagement mechanisms may be employed, e.g., detent mechanisms, bayonet locking mechanisms and the like to secure a grid relative to a base. In addition, exemplary implementations may position the engagement mechanisms at (or near) the outer circumference of the base, either instead of or in addition to the engagement mechanisms positioned internally, e.g., in association with central region 50.

In an exemplary assembly process, the pins on the base may be bent up and fed/threaded into the slits defined by the sample grids. After the sample grids are all placed on or otherwise positioned with respect to the base, the pins may then be bent back so that all of the sample grids are secured/locked with respect to the base. As noted previously, the pin/slot approach to engagement is but one exemplary approach to securing individual grids relative to the base according to the present disclosure.

When fully assembled as shown in FIGS. 1 and 4, TEM grid assembly 10 defines a substantially circular grid assembly that is sized and shaped for introduction to a conventional TEM. The outer geometry of TEM grid 10 is not limited to the circular shape of rim 13 associated with TEM grid assembly 10, but may include various geometries that can be accommodated for TEM testing, e.g., a square outer geometry, an oval outer geometry, an elliptical outer geometry, a rectangular outer geometry, and the like.

The individual sample grids may include indicia, e.g., numeric designations, that allow the user to correlate samples with test results. Thus, as shown for example in FIGS. 1 and 4, the individual grids include numeric designations (e.g., 1-6) that are visible toward the center of the assembly for easy viewing and identification. Alternative indicia may be employed, e.g., color-coding, patterned features such as nubs or apertures, and the like. In alternative embodiments, indicia may be included on the central region, rather than the grids or in addition to the indicia associated with the grids.

In exemplary embodiments, the diameter of the TEM grid assembly is generally on the order of 3 mm, although alternative diameters may be employed, e.g., 2.5 mm, 2.6 mm, 2.7 mm, 2.8 mm, 2.9 mm, 3.1 mm, 3.2 mm, 3.3 mm, 3.4 mm, 3.5 mm. The thickness of the TEM grid assembly is generally on the order of 5 to 100 microns, or alternatively 15 to 30 microns, although alternative thicknesses may be employed, e.g., thicknesses of 10 microns, 12 microns, 20 microns, 32 microns, 35 microns, 40 microns, 50 microns, 60 microns, 70 microns, 80 microns or 90 microns. The disclosed TEM grid assembly may be fabricated from copper, gold, nickel, molybdenum or combinations thereof. In exemplary embodiments, a combination of materials may be included in a single TEM grid assembly, e.g., a copper base and gold grids, or a gold base and copper grids, or a molybdenum base and a combination of gold/copper grids.

The disclosed TEM grid assembly offers significant benefits in TEM-based testing and analysis. The disclosed TEM grid assembly can save a significant amount of time for TEM users who are seeking to characterize multiple samples. In addition, the disclosed TEM grid assembly reduces the number of times that a grid must be introduced to and removed from a TEM to test/analyze a given number of samples, thereby reducing the wear-and-tear on the TEM due to the sample exchange process.

1. A TEM grid assembly, comprising:
a. a base that defines a plurality of openings; and
b. a plurality of grids configured and dimensioned for mounting relative to the base.

2. The TEM grid assembly of claim 1, wherein the base includes a plurality of spaced struts that define the plurality of openings therebetween.

3. The TEM grid assembly of claim 1, wherein the base further includes a central region.

4. The TEM grid assembly of claim 3, wherein the central region defines a plurality of engagement elements that are configured and dimensioned for engagement with corresponding engagement features associated with the plurality of grids.

5. The TEM grid assembly of claim 4, wherein the engagement elements comprise pins.

6. The TEM grid assembly of claim 4, wherein the engagement features comprise slits.

7. The TEM grid assembly of claim 1, wherein the plurality of openings are at least 15° in angular extent.

8. The TEM grid assembly of claim 1, wherein the plurality of openings are equally sized and shaped.

9. The TEM grid assembly of claim 1, wherein the plurality of openings are not equally sized and shaped.

10. The TEM grid assembly of claim 1, wherein the plurality of plurality of grids comprises 2 to 12 grids.

11. The TEM grid assembly of claim 1, wherein the base defines a substantially circular outer geometry.

12. The TEM grid assembly of claim 11, wherein the circular outer geometry is defined by a rim, and wherein the rim defines a plurality of engagement elements that are configured and dimensioned for engagement with corresponding engagement features associated with the plurality of grids.

13. The TEM grid assembly of claim 1, wherein the base is fabricated from a material selected from copper, gold, nickel, molybdenum and combinations thereof.

14. The TEM grid assembly of claim 1, wherein each of the plurality of grids is fabricated from a material selected from copper, gold, nickel, molybdenum and combinations thereof.

15. The TEM grid assembly of claim 14, wherein at least two of the plurality of grids are fabricated from different materials.

16. The TEM grid assembly of claim 1, wherein the diameter of the base is 2.5 to 3.5 mm.

17. The TEM grid assembly of claim 1, wherein the thickness of the assembly is 5 to 100 microns.

18. The TEM grid assembly of claim 1, wherein the plurality of grids include identifying indicia.

19. The TEM grid assembly of claim 1, wherein the base includes identifying indicia.

20. The TEM grid assembly of claim 1, further comprising a plurality of samples contained by the plurality of grids.
